(19) United States
(12) Patent Application Publication
(10) Pub. No.: US 2019/0390344 A1
(43) Pub. Date: Dec. 26, 2019

(54) PROCESS MODULE

(71) Applicant: MEYER BURGER (GERMANY) GMBH, HOHENSTEIN-ERNSTTHAL (DE)

(72) Inventors: JOACHIM MAI, NOBITZ (DE); DANNY MUELLER, CHEMNITZ (DE); SEBASTIAN RASCHKE, THALHEIM (DE); ANDREAS HEINZE, GEHREN (DE)

(21) Appl. No.: 16/432,548

(22) Filed: Jun. 5, 2019

Related U.S. Application Data
(62) Division of application No. 14/376,911, filed on Aug. 6, 2014, now abandoned.

(30) Foreign Application Priority Data
Feb. 6, 2012 (DE) 102012100927.9

(51) Int. Cl. C23C 16/50; C23C 16/46; C23C 16/458; C23C 16/455

(52) U.S. Cl. CPC C23C 16/50; C23C 16/463; C23C 16/45565; C23C 16/458; C23C 16/46

(57) ABSTRACT

The present invention relates to a process module comprising at least one evacuable process chamber located in the process module and at least one support device being horizontally moveable through the process module in at least one substrate transport direction for accommodating respectively at least one flat substrate which is to be processed in the process chamber. It is the object of the present invention to provide a process module of the above-mentioned type, which allows a consistent and high-quality processing of all substrates at high production speed and at the lowest device costs possible. Said object is solved by a process module of the above mentioned type in which the at least one process chamber is physically closeable with respect to the process module by means of the support device, the position of which is changeable in at least one closing direction transverse to the substrate transport direction, wherein the at least one support device forms a bottom of the at least one process chamber.

### CROSS-REFERENCE TO RELATED APPLICATION

This application is a divisional of patent application Ser. No. 14/376,911, filed Aug. 6, 2014; which was a § 371 national stage filing of international application No. PCT/IB2013/050416, filed Jan. 17, 2013, which designated the United States; this application also claims the priority, under 35 U.S.C. § 119, of German patent application No. DE 10 2012 100 927.9, filed Feb. 6, 2012; the prior applications are herewith incorporated by reference in their entirety.

### BACKGROUND OF THE INVENTION

### Field of the Invention

The present invention relates to a process module comprising at least one evacuable process chamber located in the process module and at least one support device being horizontally moveable through the process module in at least one substrate transport direction for accommodating respectively at least one flat substrate which is to be processed in the process chamber.

Large in-line devices have been proved oneself for the mass production of flat products, such as solar cells. Examples of such in-line devices are in-line roller furnaces for thermal treatment of substrates and in-line coating devices which are known, for instance, from the document WO 2011/080659 A1. In such a device, several substrates, for instance square solar cell wafers, are laid on a support device and then pass through a modular designed installation with several process modules in which a substrate treatment is carried out, respectively. A problem of cost-efficient designed in-line devices is the satisfaction of continuously increasing demands on the produced products. These include, for instance, increased demands on the gas purity during the plasma-treatment of substrates.

A high purity of plasma-treatment-devices can be realized, for instance, by using ultra-high vacuum systems and high vacuum devices. The use of such expensive devices is, however, for reasons of economy no option when producing low price products. From the document WO 2011/095846 A1, also parallel plate reactors are known which meet high demands on a plasma-based CVD-deposition and which are associated with relatively low device costs. There is, however, always the desire to increase the quality of products by simultaneously reducing production costs.

### SUMMARY OF THE INVENTION

Therefore, the object of the present invention is to provide a process module of the above-mentioned type, which allows a consistent and high-quality processing of all substrates at high production speed and at the lowest device costs possible.

Said object is solved by a process module of the above mentioned type in which the at least one process chamber is physically closeable with respect to the process module by means of the support device, the position of which is changeable in at least one closing direction transverse to the substrate transport direction, wherein the at least one support device forms a bottom of the at least one process chamber.

This process module is based upon the chamber-in-chamber-principle. The process module thereby forms an outer chamber, in which the process chamber is applied as an inner chamber. The process chamber can thereby be attached to a chamber lid of the process module and/or is supported by specific support elements from the bottom. In some cases, the process chamber can be attached to an intermediate ceiling respectively an intermediate bottom and/or to side walls of the process module. The manner of the attachment-type is influenced and defined by the technical and technological requirements of the process chamber and/or the process module.

By implementing said structure, a better separation of the treatment region from the outer atmosphere respectively from supporting devices, which, for instance, are needed for the transport of the substrate within the process module, is obtained than by using a single chamber. This way, the concentration of impurity gases in the process chamber can also be reduced and the accuracy of the temperature settings of the process chamber can be increased. Since plasma treatment processes such as a plasma-enhanced chemical vapor deposition are temperature-dependent, an increased accuracy of the temperature setting also increases the quality of the homogeneity of the substrate processing. Another advantage is that the immediate process region for the substrate processing can be separated in such a way that the transient effects, which are mainly dependent on the gas exchange, can run in a more defined and shorter manner when turning on the plasma.

The process chamber of the process module of the present invention is realized in a simple and cost-efficient way by the support device forming the bottom of the process chamber. The already existing support device is thereby forming both the bottom and the closure of the process chamber. Therein, only the side of the support device, on which the at least one substrate is provided, is in the process chamber. The other elements of the support device are outside the process chamber. Thus, the inner volume of the process chamber can be minimized, whereas pump-down times, flush times, and ventilation times can be decreased and costs can be saved subsequently.

Several process chambers can be arranged in the process module. There can be, for instance, two process chambers, as further explained below, whose bottoms are formed by two support devices.

According to the invention, the support device is horizontally moveable inside the process module. The process module can be formed, for instance, as module of an in-line device. In such a case, there is only one substrate transport direction, the in-line direction through the in-line device. The process module can also be another embodiment an end module, which only has one opening for the supply and further transport of at least one support device. In this case, there are two substrate transport directions, one loading direction being opposite one unloading direction.

Depending on the transport device used, the substrate transport direction can be a one-dimensional movement direction or a curved movement direction. The movement of the transport device in the substrate transport direction does not just yet lead to the closing of the process chamber. To close the process chamber, the support device in the closing direction is moved towards the direction of the immovable parts of the process chamber. The closing direction is usually an upwards directed vertical movement, but can also be a movement at an angle to the vertical. In any case, the closing direction is not identical to the substrate transport direction, but the closing direction is oriented transversely, that is at a large angle, towards the substrate transport direction. Because of the movement of the support device in the closing direction, the process chamber can be closed. Because of the movement of the support device opposite the closing direction, the process chamber can be opened accordingly again, respectively, the distance between the support device and the process chamber can be increased. The processing in the process chamber usually takes place in a closed process chamber. Processes, however, can also be provided in an opened process chamber.

In a favored embodiment of the process module of the present invention, the at least one support device is electrically conductive or has at least one electrically conductive surface. The transport device can thereby form an electrode, which is coupled electrically to the plasma and causing a movement of load carriers from the plasma towards the direction of the support device. The support device has to be electrically conductive to form a current circuit containing the plasma and the support device.

In addition, the surface of the support device must be comprised of a process compatible material in the inside of the process chamber. That is, the support device must not be damaged by running processes in the process chamber, and no impurities must be brought into the process chamber by the support device. When, for instance, a CVD-deposition of silicon nitride and a chamber cleaning with a chlorine-containing and/or fluorine-containing cleaning gas are alternately carried out in the process chamber, aluminum qualifies as process compatible material. There is a good adhesion between aluminum and silicon nitride so that no premature particle formation is to be feared by spallings. Further, aluminum is resistant against various etching gases so that no undefined corrosion at the support device occurs in the purification processes. Other material properties are necessary to achieve the process-compatibility in other processes. For instance, oxidizability for an oxygen-plasma-processing or high temperature resistance for a high-temperature-processing can be required.

According to an advantageous embodiment of the process module of the present invention, connections of the process chamber for gaseous, liquid, and/or electric media are arranged in a ceiling and/or in at least one side wall of the process chamber. For the processing in the process chamber, a defined atmosphere is usually needed. To provide this defined atmosphere, certain gases have to be supplied. Other gases, for instance, the reaction products of a chemical gas phase reaction, have to be pumped away from the process chamber. Sometimes, liquid media such as cooling water have to be filled into the process chamber. Moreover, electrical energy has to be inserted into the process chamber to produce plasma. The different connections of each media are preferably provided in the immovable parts of the process chamber that is in the ceiling or in at least one of the side walls of the process chamber. Immovable connections are usually easier and more reliable than moveable connections. The connections can be arranged in one wall of the process chamber or can be distributed over several walls.

The processing of the substrate is primarily provided in the process chamber. Thus, only the evacuable process chamber can be provided with a pump connection. In this case, the outside region around the process chamber of the process module is rinsed through the pump connection of the process chamber or through the pump connection of a neighboring module of the process module. In a more advantageous modification, the process module comprises, however, its own pump connection so that gases, for instance, for the reduction of impurities, can be evacuated from the process module independent of the process chamber. In addition, it is advantageous when the process module has its own gas inlet.

In an advantageous example of the process module of the present invention, the process module comprises at least one tempering element for the tempering of the ceiling and/or at least of one side wall of the process chamber, wherein the tempering element is a heating device and/or a cooling device. The temperatures can be adjusted particularly reliable during the processing, if not only the substrates but also the whole process chamber is tempered. Different tempering elements can be used corresponding to the processing temperatures used. The tempering element is regularly formed as heating device if high temperatures are required. The heating device can be, for instance, a resistance heating or a lamp heating. For example, it can also be required that the process chamber needs to be cooled or that the temperature can be adjusted from cooling to heating. Tempering elements, comprising of a combination of a cooling device and heating device or having an adjustable temperature, can be used for such tasks. A temperature control is possible, for instance, by a temperature-controlled liquid.

In a further embodiment of the process module of the present invention, the process chamber comprises at least one HF-compatible connection or contact for the support device. If the support device is used as electrode for an HF-plasma, the support device has to be embedded into a HF-circuit. There are other requirements on electric conductors for HF-currents than on conductors for direct currents. Therefore, a connection or a contact for the support device is provided for the electrical connection of the support device. When using a contact, the electrical connection is made by only pressing the support device, whereas when using a connection, the electrical connection is made by mechanics. This connection or contact is preferably a component of the process chamber. In alternative embodiments, the connection or contact can also be at least to some extent part of the support device and/or the process module.

The HF-compatible connection or contact is usually a ground connection. That is, the support device is connected through the connection or contact to ground so that the HF-current can flow towards ground. Alternatively, the connection or contact can also be isolated from the ground so that a different potential than ground potential or an ac voltage can be applied to the support device. When applying an alternating voltage, different goals can be pursued. In an example, the HF-power can be coupled to generate plasma in the process chamber. In another example, the support device can be charged with a potential to extract ions from plasma generated elsewhere. The charge of the support device with a different potential than ground potential is, however, very complex since a plasma ignition outside the process chamber and at the edge region in the process chamber must be avoided constructively by using suitable insulators. The HF-contact can be formed either as physical, mechanical contact or as capacitive contact. A capacitive contact can, for instance, be formed through an electrode plate which is parallel to the support device.

According to a favored constructive design, the process module of the present invention comprises a transport system for a supply of the support device to the process chamber and/or for the unloaded of the support device from the process chamber, wherein the supply and/or discharge being in a transport region parallel to a horizontal tension of the process chamber. Amongst others, the process module of the present invention can be adjusted for the processing of mechanically large support devices. To move large and heavy substrates and support devices, transport devices such as robotic arms, which are used for small and light substrates, are poorly suited. For the transport of the support device transport devices are advantageous which also provide a support of the support device inside the process module. The transport device used thereby realizes a horizontal movement of the support device, which is loaded with substrates, towards the process chamber and away from the process chamber after the processing. In an in-line device, the movement direction of the support device corresponds to the in-line direction. In other device, the transport direction away from the process chamber can be opposite to the transport direction towards the process chamber.

In particularly suitable embodiments of the process module of the invention, the transport system comprises transport rollers and/or a linear motor drive. A regular or continuous support of the support device can be realized through transport rollers and linear motor drives so that no sagging or bending of the support device occurs. Thereby, the process module can be formed compactly and no room must be provided for sagging transport devices. The transport system, however, does not necessarily has to have transport rollers or a linear motor drive, other solutions of transport devices are possible, for instance, a supported transport arm.

It is in particular advantageous if all drive components of the transport system of the process module of the present invention are arranged outside of the process chamber. This way, the process chamber can be formed particularly flat and the drive components of the transport system are not exposed to any load caused by the process in the process chamber.

In a favored embodiment of the process module of the present invention, the process module comprises a lift system for lifting the support device to a processing level and for lowering the support device to a transport level, wherein the support device of the processing level functions as bottom of the process chamber. In this embodiment, the transport mechanics for the support device is separated from the locking mechanics for the process chamber. An easy transport of the support device in the transport level is possible, wherein no mechanical adjustment between process module and support device is necessary because of sufficiently large distances. The closing of the process chamber is realized with the help of a lift system, which presses the support device against the immovable parts of the process chamber, so that the support device forms the bottom of the closed process chamber. The lift system executes a basically vertical lift movement, at which the support device is pushed against sealing surfaces. This way, a good sealing of the process chamber is achieved. Primarily, the operation of the process chamber is running when closed, wherein the support device is located in the processing level. However, the lift system can also lower the support device to levels, which are situated under the processing level. In these levels, processes such as cleaning processes are also possible. Alternatively, the process module can also be realized without a lift system, wherein the closure of the process chamber is realized through different mechanics, for instance, by an inclined plane.

In an advantageous development of such a process module of the present invention, the lift system comprises at least one heating plate or one radiation heating. The substrates shall have a defined temperature in the process chamber. The lift system is arranged in spatial proximity to the substrates laying on the support device and thus, a suitable place for a substrate heating. To adjust or maintain the substrate temperature, a heating plate being arranged close to the substrates or a radiation heating, which delivers the necessary heat to the substrates to maintain the substrate temperature is suitable. Preferably, the substrates are transported pre-heated with increased temperature so that the heating plate or the radiation heating only has to deliver the heat derived and radiated from the substrates.

A good thermal contact between heating plate and the support device can be realized in an evacuable process module, for instance, through a shock coupling, in which a heat transfer is provided by means of gas particles. When shock coupling, a gap is formed between the heating plate and the support device by the arrangement of heating plate and support device or by a defined profile or the roughness of the surface(s) of heating plate and/or support device, wherein the mean distance between the heating plate and the support device is about the mean free path of the gas particles in this gap. With such a gap, the gas particles hardly contact each other in their thermal movement, but rather contact the support device and the heating plate so that an efficient heat transfer through the gas is possible. In an embodiment, a mean distance between heating plate and support device respectively a gap width of about 50 μm can be provided, wherein a pressure dependent on the gas type of 2 . . . 20 mbar can be optimal in the gap. A gas which is, for instance, already present in the process module such as helium or hydrogen can be used as gas for the shock coupling. To reduce the gas consumption, the gap is limited by a seal. Such a good heat transfer is advantageous for an exact temperature control of the support device and thus, of the substrates, too. Thereby, the heating plate cannot only be used as heat source. The heating plate can also at least partly serve as cooling plate, into which otherwise with substrates introduced heat of the support device can be derived.

A similar approach can also be applied within the process chamber between the at least one substrate and the support device, to also reach an improved thermal coupling in there. This way, for instance, the upper side of the support device can be formed with a defined roughness.

In a particularly beneficial embodiment of the process module of the present invention, the heating plate or the radiation heating is liftable and lowerable. The liftable and lowerable heating plate or radiation heating can be coupled to the lifting and lowering movement of the support device, thereby maintaining a constant heating even when the support device is lifted.

In another embodiment, the lift system comprises heat isolation blocks with a low thermal conductivity, wherein a carrier of the support device is provided on the heat isolation blocks. There is little heat conduction between support device and lift system because of the low heat conductivity of the heat isolation blocks, and the lift system can be kept at a lower temperature favorable to the mechanical strength of the support device. A homogenous temperature of the support device despite a missing carrier on heating plates can be ensured, for instance, by using a radiation heating.

In a preferred embodiment of the process module of the invention, the lift system comprises a lifting frame holding the support device at its side. The substrates are regularly lay centrally on the support device, and the edge regions of the support device are used as sealing regions for closing the process chamber. Therefore, the demands on the temperature uniformity are low at the edge regions of the support device, so that the mechanical forces for sealing the process chamber can be transferred particularly suitable. The pressing forces are transferred directly onto the sealing regions through the lifting frame, which holds the support device at its side(s), and the heat dissipation by the lifting frame has hardly any effect on the substrate temperature.

In an advantageous development of the invention, a heat insulating pressure body with a flat carrier surface forms a carrier of the lifting frame. Little heat is transferred through heat insulators, so that the temperature of the support device is very little affected by the heat insulating lifting frame. The lifting and closing force is transferred evenly and over a large area to the support device by the design of the lifting frame as pressure body with a flat carrier surface, so that the support device can be formed with a relatively light weight and in a cost-efficient way.

As mentioned above, it is favorable, when the process chamber of the invention has at least one seal, wherein the support device is pressed against said seal to close the process chamber. In other embodiments, the seal can also be provided at the support device. A good separation between the inner process chamber from the outer process module is achieved by a seal, so that a high degree of purity can be reached inside the process chamber, wherein the gases from the process chamber, which can be toxic, if the process chamber is closed, cannot pass to regions around the process chamber of the process module. However depending on the processes running in the process chamber and the structure of the process module, a closure of the process chamber without a seal can also be provided. Thereby, a high purity of the process chamber can be reached, for instance, by a gas flow directed from the interior to exterior, where in the flow velocity of the gas is higher than the diffusion rate of foreign gases from the exterior to the interior.

In another advantageous embodiment, the process module of the invention comprises at least one support roller as support of the support device. The support device can be susceptible to mechanical bendings because of the large mechanical dimension of the support device being possible in the invention. The occurring forces can be divided through supports, wherein the bendings are reduced proportionally to the divided forces. The support is advantageously formed as support roller, which can be operated with low levels of friction and wear. The planarity of the support device, however, can not only be ensured by supports, there are also other solutions. The support device, for instance, can be convex-arced, being pressed flat through the outside pressure, which acts on the evacuated process chamber.

It is in particular advantageous, if at least one area of the process module, which surrounds or is adjacent to the process chamber, can be filled with gas. A desired atmosphere can be created in the process module by filling same with a gas. By filling the process module with gas, a desired atmosphere can be created in the process module. Thereby, the gas can be either an inert gas or an oxidizing or a reducing gas. The gas in the process module can be stationary or flowing. Thereby, the process module can be a vacuum chamber. The process module can also be a vacuum chamber which is operated under atmospheric pressure. The process module can also be a chamber operated under atmospheric pressure, which is not evacuable. Such a non-evacuable chamber can be produced particularly cost-efficient.

In a further development, the process module of the invention comprises at least one evacuable, the process chamber surrounding isolation chamber, wherein the isolation chamber comprises at least one isolation chamber door. In this embodiment of the invention, three chambers are nested within each other. The process chamber is located internally, the process chamber is surrounded by the isolation chamber, and the isolation chamber is surrounded by the process module. A triple nesting allows an even better thermal and chemical insulation of the process chamber against the surrounding than a double nesting would provide. Such sophisticated and highly developed chambers can be, for example, useful when safety requirements are increased due to the processing of highly toxic substances or when particularly high requirements on temperature uniformity are demanded. The isolation chamber can also be used for the separation of a process chamber operating while open from the process module. An open process chamber while operating is useful, for instance, for cleaning processes, which shall also clean the edges of the support device.

According to another embodiment, the process module of the invention comprises at least one evacuable isolation room adjacent to the process chamber. Providing an isolation room, existing requirements can be specifically met. A good thermal insulation of the ceiling of the process chamber and/or a homogenous horizontal temperature distribution can be realized, for instance, by an isolation room adjacent to the ceiling of the process chamber. No thermal insulation, however, is in this case present at the side walls of the process chamber as is the case when using an isolation chamber. In another embodiment, the vacuum is provided as electrical insulator for a HF-distribution which is located in the isolation room. The object of the isolation room can also be to form an additional chemical separation between process chamber and process module. In this case, the isolation room provides an additional space sealing the process chamber. Such an isolation room can, for instance, be formed as differentially pumped interspace between two seals.

In a preferable embodiment of the process module of the invention, the process chamber is made of aluminum or an aluminum alloy or internally coated with aluminum or an aluminum alloy. Aluminum has a range of advantageous properties. For instance, aluminum has a low density, so that support devices made of aluminum have a low weight. Moreover, aluminum has a good electrical and thermal conductivity. The surface of aluminum forms a chemically stable and mechanically thin aluminum oxide layer. In practice, aluminum proves to be stable in cleaning processes, for which, for instance, etching gases such as NF₃, SF₆or chlorine containing etching gases respectively also fluorohydrocarbons can be used. Furthermore, a contact of aluminum with a semiconductor such as silicon is less problematic than, for instance, an impurity of the semiconductor with copper. When using aluminum alloys, advantageous alloy properties are additionally used to the advantageous properties of aluminum.

According to an further developed version of the process module of the invention, at least two process chambers in a vertical stack arrangement are provided. The production rate can be nearly doubled through the arrangement of two process chambers in one process module. Since both process chambers share one process module, the device and running costs rise, however, to a smaller degree than the productivity does. So, a shared pump device can be provided, or devices for the distribution of media to several process chambers can be used together.

In an embodiment, this special process module of the invention comprises a lift for a vertical transport of the support device into at least two transport levels. The lift can move a support device between process chambers and transport levels, one above the other, so that a specific production cycle can be realized in the process module. Thereby, two or more process chambers can be run with the same process, wherein the logistics for the use of all process chambers is guaranteed with the help of the lift. The process chambers, however, can also run various complementary processes, wherein the lift is then used for the realization of the desired process sequence.

In a preferable embodiment of the process module of the invention, the process chamber is a plasma chamber, which has a gas shower acting as a first HF-electrode, wherein the gas shower forms a parallel plate arrangement with the support device. Parallel plate reactors are established devices in which high-quality processing results are achieved. Such parallel plate reactors are preferably operated with excitation frequencies between 10 kHz and around 100 MHz or also mixed excitation frequencies. Depending on the concrete dimensions of the HF-electrode, several connections for the input of HF-power or also of gas connections can be provided. Thereby, for instance, a more homogenous distribution of the electrical current on the electrode can be reached especially at higher excitation frequencies. Here, the excitation frequencies can be pulsed over time as well as continuously provided. The plasma excitation with pulsed direct voltage, however, can also be advantageous. By using the plasma, processing at relatively low temperatures and yet high processing speed is usually possible. The process chamber does not necessarily has to be a parallel plate arrangement. For instance, an in-line arrangement of linear microwave plasma sources can also be used in the process chamber. The process chamber can also be formed for a process without plasma. Possible plasma-free processes are, for instance, a catalytic deposition, “Low Pressure CVD (LPCVD)”-processes, “Atomic Layer Deposition (ALD)”-processes and thermal treatments.

According to an optional embodiment of the process module of the invention, the process chamber is a plasma chamber, which has an arrangement of several plasma sources. There are many possibilities how to produce plasma in a plasma chamber with specific advantages and disadvantages. In some types of plasma chambers, only one plasma source, for instance, as a parallel plate arrangement, is provided in the process chamber. In other types of plasma chambers, several plasma sources can be used to produce locally acting plasma regions or to produce a plasma acting on a large area. This can be, for instance, microwave plasmas, which are characterized by high charge carrier densities and high deposition rates.

According to an embodiment, the process module of the invention comprises at least one magnetic field arrangement arranged in or at the process chamber, wherein the magnetic field arrangement is either fixed or moveable. An advantageous influence of the plasma production and hence, for instance, on the processing homogeneity, processing quality and/or the processing speed can be reached by additional magnetic arrangements, whose magnetic fields act through walls of the process chamber and/or support device in a defined manner. These magnetic arrangements can be either fixed, or can be moved along the partition walls of the process chamber and/or the support device in a defined manner. In another embodiment, defined magnetic arrangements can be arranged within the process chamber. Magnetic arrangements can, thereby, be either permanent magnet systems or electric coil systems with or without pole-shoe-arrangement.

In a preferable embodiment, the process module of the invention comprises at least one module interface with a module door for the integration of the process module into the substrate processing device. A substrate processing device in a manufacturing environment comprises, besides a process module, usually further components such as lock modules, other process modules and measuring modules. To couple the substrate processing device with the process module, a module interface is therefore required. The module interface shall preferably be a standardized interface, allowing a flexible construction of substrate processing systems of various components. Thereby, the module interface preferably has a module door, which can be closed and opened. By the closed module door, the process module and the atmosphere contained therein can be separated from the rest of the substrate processing device, so that impurities in the substrate processing device are kept away from the process module. When the module door is opened, a transport of the support device between the substrate processing device and the process module is possible through the module door.

Other features which are considered as characteristic for the invention are set forth in the appended claims.

Although the invention is illustrated and described herein as embodied in a process module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 schematically shows an embodiment of a process module of the invention in a vertical cross section along a substrate transport direction;

FIG. 2 schematically shows the process module of FIG. 1 in a vertical cross section opposite to the substrate transport direction;

FIG. 3 schematically shows a further embodiment of the process module of the invention with two process chambers stacked vertically;

FIG. 4 schematically shows a next embodiment of the process module of the invention with a process chamber included in an insulation chamber;

FIG. 5A-5C schematically shows a loading sequence of the process module as shown in FIG. 4;

FIG. 6 schematically shows a further embodiment of the process module of the invention with two process chambers stacked vertically with media connections at their sides;

FIG. 7 schematically shows the process module of FIG. 6 with two process chambers surrounded by insulation chambers and lift systems in a vertical cross section; and

FIG. 8 schematically shows another embodiment of the process module of the invention with isolation rooms above and beneath the process chamber.

### DETAILED DESCRIPTION OF THE INVENTION

The following is a summary list of reference numerals and the corresponding structure used in the above description of the invention:

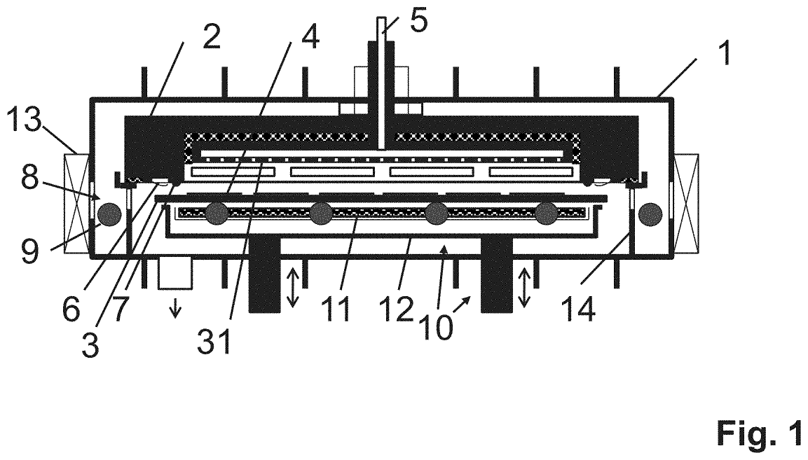

FIG. 1 schematically shows an embodiment of a process module of the invention in a vertical cross section along a substrate transport direction. Within the process module 1, a process chamber 2 is arranged. As bottom of the process chamber 2, a support device 3 is used, on which substrates 4 lay. The process chamber 2 shown exemplarily in FIG. 1 is a parallel plate reactor for a plasma-enhanced deposition of layers on the substrates 4.

The gaseous starting substances for the layer deposition are introduced into the process chamber 2 through a gas connection set 5 in a gas shower 31. The gas shower 31 serves as a first HF-electrode in the parallel plate reactor. The support device 3 with the substrates 4 is the second electrode of the parallel plate reactor being directed parallel to the gas shower 31.

An electrical connection of the support device 3 with the HF current circuit is required so that electronic HF-power can flow from the gas shower 31 across the support device 3. This electrical connection is provided by an HF-compatible contact 6, as is shown by the embodiment shown in FIG. 1, which is a mass contact in the embodiment shown. Besides the HF-compatible contacts 6, a seal 7 is arranged, sealing the process chamber 2 against the process module 1 when the support device 3 is lifted.

The support device 3 as shown in FIG. 1 is located in a transport level and can be moved horizontally in the substrate transport direction by means of a transport system 8. In the embodiment shown, the transport device 8 is a roller transport system comprising transport rollers 9. The transport system 8 is here only used for the transport of the support device 3 into the transport module 1 and for the transport out of the transport module 1 and not for locking the process chamber 2.

To lock the process chamber 2 with the support device 3, a lift system 10 is used. For that purpose, the support device 3 is centrally arranged under the process chamber 2. Afterwards, the support device 3 is lifted by the lift system 10, wherein the support device 3 is placed on a lifting frame 12. Within the lifting frame 12, a heating plate 11 is provided, which heats the support device 3 and the substrates 4 laying thereon and thus, heats to the desired process temperature.

For the storage of the process chamber 2 in the process module 1, carriers 14 are used for the process chamber 12. The process module 1 is provided as a module of a substrate processing system, which is connected to the substrate processing system through module interfaces. On each module interface a module door 13 is provided, which can be closed to separate the process module 1 from the substrate processing system. In the embodiment shown, two substrate doors 13 are provided so that an in-line of the support device 3 through a module door 13 into the process module 1 and through the other module door 13 out of the process module 1 is possible.

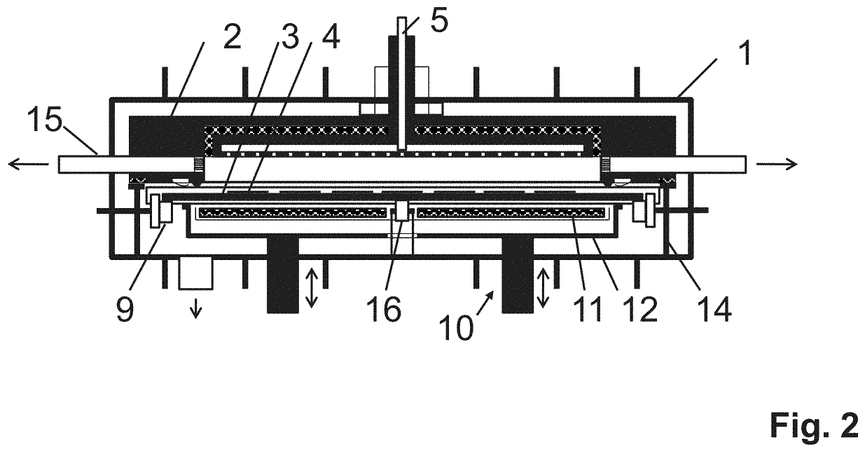

FIG. 2 schematically shows the process module 1 of FIG. 1 in a vertical cross section opposite to the substrate transport direction. Some elements of the process module 1 have already been described above with reference to FIG. 1. As can be seen in FIG. 2, the transport rollers 9 present are stub rollers with a lateral guidance for the support device 3. The support device 3 as shown in FIG. 2 is in the transport level, wherein the support device 3 is centrally arranged on a support roller(s) 16 or several sequentially arranged support rollers 16. A bending of the support device 3 is avoided by the use of the support roller 16. Between the transport rollers 9 and the support roller 16, a heating plate is arranged respectively. In another embodiment of the invention, it is also possible to provide a recessed heating plate in the region of the support roller(s) 16. Lateral process chamber pump units 15 can be clearly seen in FIG. 2, which are only shown as rectangles in the background of FIG. 1. Used gases are evacuated through the process chamber pump units 15 from the process chamber 2, wherein the flow direction in the embodiment shown is optimized by flow baffles.

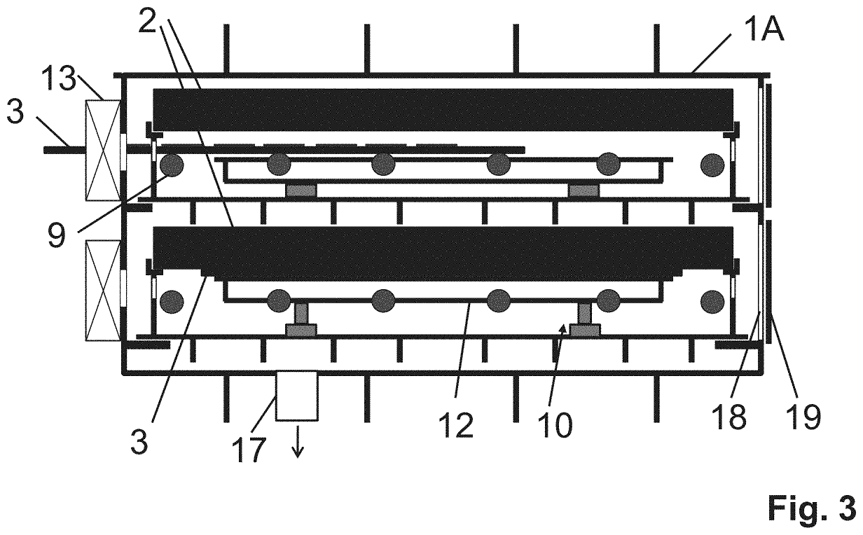

FIG. 3 shows a further developed process module 1A of the present invention, which provides two process chambers 2 in a vertical arrangement. The process chambers 2 have already been described in detail above with reference to FIG. 1 and FIG. 2 and thus, are only illustrated highly schematic in FIG. 3. The process module 1A is formed as end module and not as in-line module as is the case of the process module 1 shown in FIG. 1. When using the end module, both the evacuation of the support device 3 and its evacuation after the processing through the same module door 13. Regarding the upper process chamber 2, the support device 3 is shown in a position during the transport. With regard to the lower process chamber 2 in FIG. 3, the support device 3 is lifted by the lift system 10 to the processing level, and thus forming the bottom of the process chamber 2. The process module 1A encloses both process chambers 2. The gas from the process module 1A is evacuated through a pump unit 17. As can be seen on the right side of the illustration of FIG. 3, the process module 1 provides two inspection openings 18, which are closed by a revision closure element 19, respectively. Maintenance work is possible in the process module 1A because of the inspection openings 18, and the process chambers 2 can be brought inside and outside of the process module 1A through these inspection openings.

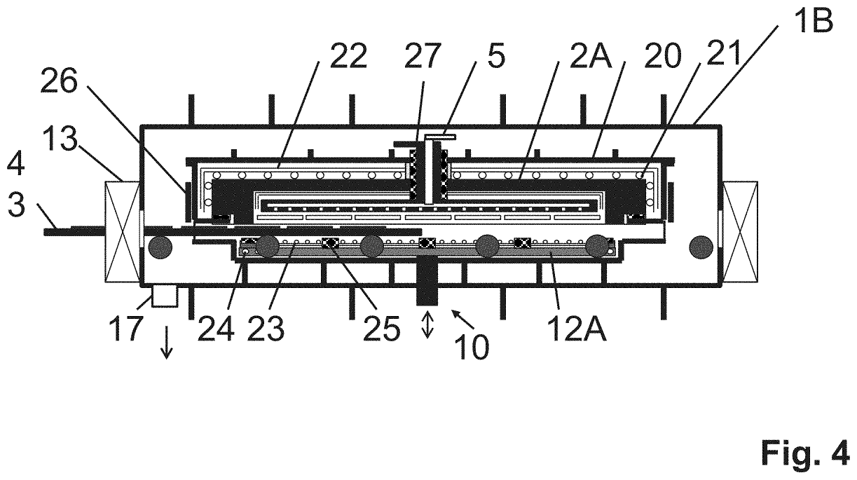

FIG. 4 shows another embodiment of the process module 1B of the invention, at which a process chamber 2 can be locked inside an insulation chamber 20. The insulating chamber 20 can be closed with insulation chamber doors 26, so that the process chamber 2A is double delimited from the outside atmosphere. In the embodiment shown, within an insulating chamber 20, process chamber tempering elements 21 and heat reflectors 22 are shown. The process chamber tempering elements 21 present are heating rods, which can transfer their temperature partly through heat conduction and partly through radiation to the process chamber 2A. In other non-illustrated embodiments, other process chamber tempering elements such as pipes, through which a tempered liquid flows, can also be used. Below the support device 3, a radiation heater 23 is shown, which is spatially separated from the support device 3 through heat isolation blocks 25, and which transfers its heat to the support device 3 through heat radiation. The lifting frame 12A provides cooling elements 24, which consist of channels capable of transporting cooling liquid. By using cooling elements 24, an overheating of the lifting frame 12A can be avoided.

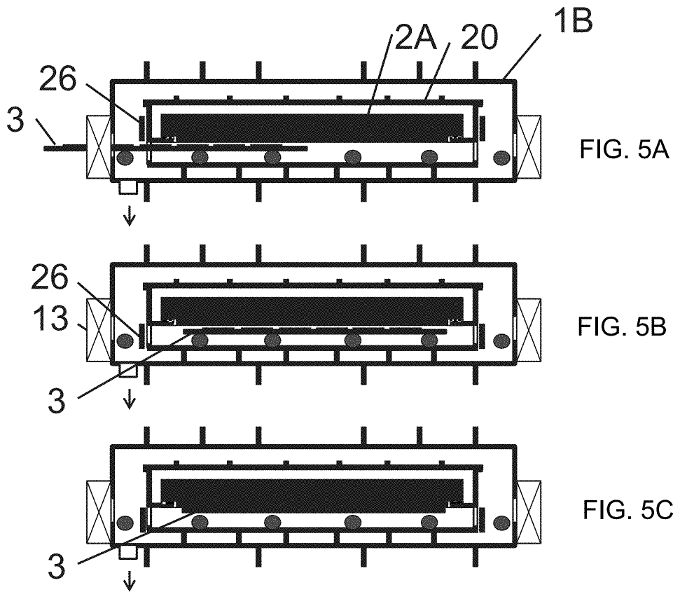

FIG. 5 is a schematic illustration of a loading sequence of the process module 1B, which has already been described in FIG. 4. In FIG. 5A, both insulation chamber doors 26 are opened, and the support device 3 runs from left to right into the insulation chamber 20. In FIG. 5B, the support device 3 is centrally arranged below a process chamber 2B. The insulation chamber doors 26 are closed now, and in the insulation chamber 20 a different pressure can be adjusted than in a process module 1B. The process chamber 2A is, however, still open and the pressure in a process chamber 2A and in the insulating chamber 20 is, therefore, at the same level. In FIG. 5C, the process chamber 20 is closed, and in the process chamber 20, a different pressure than in the insulating chamber 20 can be adjusted, which in turn can be a different pressure than in the process module 1B. The unloading sequence is not shown, but can be realized without further instructions by a person skilled in the art on basis of his expertise.

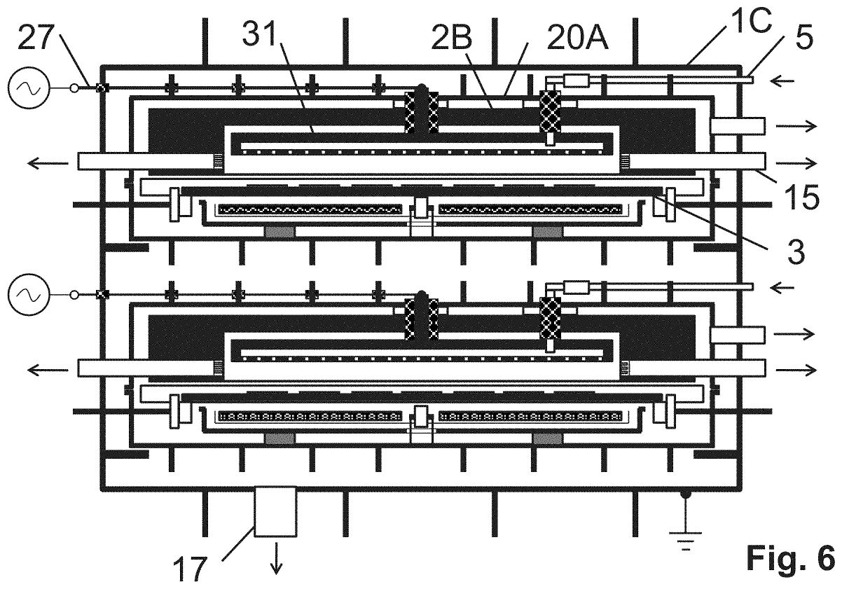

FIG. 6 schematically shows a further process module 10 of the present invention with two vertically stapled process chambers 2B located in an insulating chamber 20. As is shown in the embodiment of the process chamber 10, an HF-inlet 27 comes out of a side wall of the process chamber 1C and is centrally connected to a showerhead 31. The gas connection set 5 is also fed out laterally from the process module 1C, thereby a constant gas emission from the shower head 31 in direction to a substrate 4 is ensured through the construction of the shower head 31.

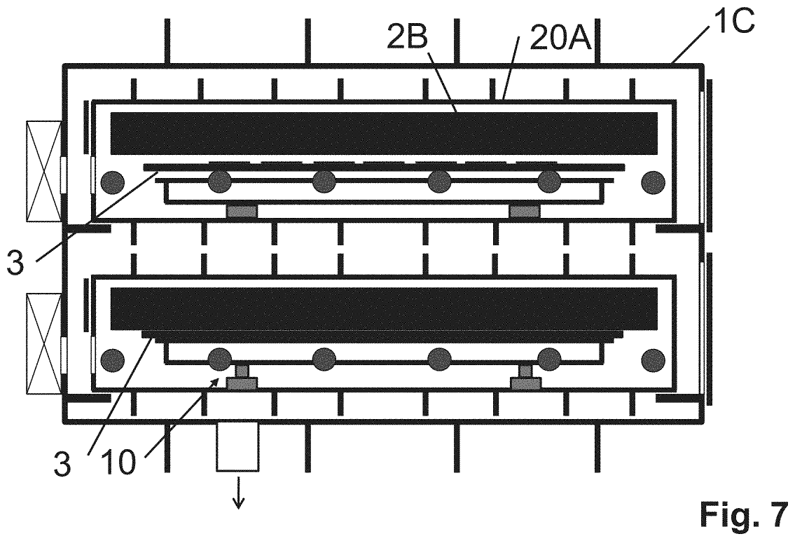

In FIG. 7, the process module 10 illustrated in FIG. 6 is schematically shown in a vertical cross section along the substrate transport direction. The upper process chamber 2B is shown in an open state, wherein the lift system 10 is lowered. On the contrary, the lower process chamber 2B is closed, wherein the lift system 10 is extended and holds the support device 3 in the process level.

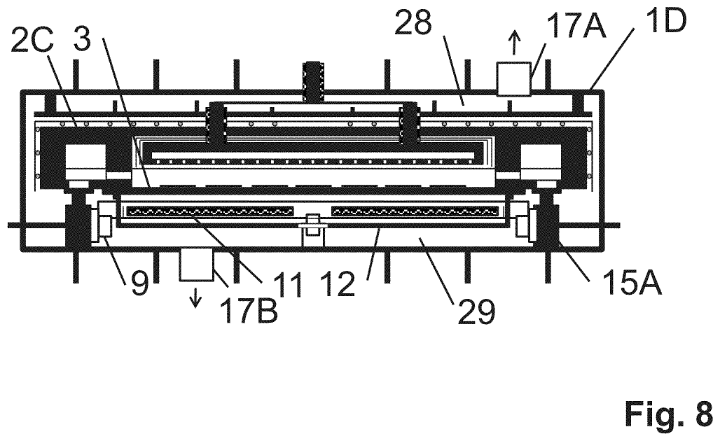

FIG. 8 schematically shows another process module 1D of the present invention, which comprises an upper insulating room 28 and a lower insulating room 29. In this embodiment, the process chamber 2C is not completely surrounded by an insulation chamber, instead isolation rooms 28, 29 are only provided above the upper side of the process chamber 2C and below the support device 3. A good thermal insulation of the process chamber 2C is achieved by the isolation rooms 28 and 29. The upper isolation room 28 can advantageously contain a HF-distributor for the distribution of HF-energy to different feeding points of the HF-electrode. Depending to the set pressure and chosen gas, a plasma ignition at the HF-distributor can be avoided.

The isolation rooms 28 and 29 comprise separate pump units 17A, 17B. This way, they can be evacuated independent of the process module 1D.

Besides the embodiments shown of the process modules 1, 1A, 1B, 1C, 1D, other non-illustrated process modules of the invention can be realized, at which the single elements shown can be arranged or combined differently and/or at which equivalent elements can be used.

1. A process module, comprising:
an evacuable process chamber disposed in the process module;
at least one support device being horizontally moveable through the process module in at least one substrate transport direction for respectively accommodating at least one flat substrate to be processed in said process chamber, said at least one support device defining a bottom of said process chamber in said processing level;
a lift configured to lift said at least one support device to said processing level and to lower said at least one support device to a transport level, said lift including a radiation heater, said radiation heater being configured to be lifted or lowered said lift including thermal insulation blocks, and said at least one support device having a carrier provided on said thermal insulation blocks;
said at least one support device being configured to physically close said process chamber;
said at least one support device being configured to change position in at least one closing direction transversely to said at least one substrate transport direction, relative to the process module; and
said at least one support device forming a bottom of said process chamber.

2. The process module according to claim 1, wherein said at least one support device is electronically conductive or at least includes an electrically conductive surface.

3. The process module according to claim 1, wherein said process chamber has a ceiling, side walls and connections disposed in at least one of said ceiling or at least one side wall for at least one of gaseous, liquid or electronic media.

4. The process module according to claim 1, which further comprises at least one pump connection associated with said process module and at least one pump connection associated with said process chamber.

5. The process module according to claim 1, wherein said process chamber has a ceiling and side walls, at least one tempering element of the process module is configured to temper at least one of said ceiling or at least one side wall, and said at least one tempering element is at least one of a heating device or a cooling device.

6. The process module according to claim 1, which further comprises a transport system of the process module configured to transport said at least one support device to and away from said process chamber and to provide a supply or discharge in a transport level parallel to a horizontal extension of said process chamber.

7. The process module according to claim 6, wherein said transport system includes at least one of transport rollers, a linear motor drive or a transport arm.

8. The process module according to claim 1, wherein said lift includes a lifting frame having a side holding said at least one support device.

9. The process module according to claim 8, which further comprises a heat-insulating pressure component with a flat carrier surface providing a carrier for said lifting frame.

10. The process module according to claim 1, wherein the process module is configured to be filled with a gas.

11. The process module according to claim 1, which further comprises at least one evacuable isolation chamber of the process module surrounding said process chamber, said at least one isolation chamber having at least one isolation chamber door.

12. The process module according to claim 1, wherein said process chamber is made of aluminum or an aluminum alloy or has an inside covered with aluminum or an aluminum alloy.

13. The process module according to claim 1, wherein said process chamber is a plasma chamber having a gas shower serving as a first HF-electrode, said gas shower forming a parallel plate configuration with said at least one support device.

14. The process module according to claim 1, which further comprises at least one module interface of the process module having a module door for an integration of the process module into a substrate processing device.
